(19) United States
(12) Patent Application Publication
(10) Pub. No.: US 2006/0292501 A1
(43) Pub. Date: Dec. 28, 2006

(54) Lithography process with an enhanced depth-on-focus

(75) Inventor: Jen-Chieh Shih, Yongkang City (TW)

Correspondence Address: HAYNES AND BOONE, LLP, 901 MAIN STREET, SUITE 3100, DALLAS, TX, 75202, US

(73) Assignee: Taiwan Semiconductor Manufacturing Company, Ltd., Hsin-Chu (TW)

(21) Appl. No.: 11/166,535

(22) Filed: Jun. 24, 2005

(51) Int. Cl. G03F 7/20

(52) U.S. Cl. 430/322; 430/327; 430/950

(57) ABSTRACT

Provided is a method for lithography processing. The method comprises forming a photoresist layer on a substrate and forming a resolution enhancement material (REM) layer on the photoresist layer. The REM layer comprises an acid component.

### BACKGROUND

In semiconductor technology, an integrated circuit pattern can be defined on a substrate using a photolithography process. One factor associated therewith is a depth of focus (DOF), which identifies a distance along an optical axis over which features of a semiconductor device are in focus. An effective DOF covers variations of photoresist thickness, local substrate topology step height, and wafer center and edge step height differences. Accordingly, an effective DOF enables a semiconductor device to be manufactured within specified critical dimensions (CD) without scumming (e.g., inadequate development), top loss defects, or other undesirable issues. However, the DOF is limited by the performance of a photoresist layer having photoacid generator (PAG) therein.

### BRIEF DESCRIPTION OF THE DRAWINGS

Aspects of the present disclosure are best understood from the following detailed description when read with the accompanying figures. It is emphasized that, in accordance with the standard practice in the industry, various features are not drawn to scale. In fact, the dimensions of the various features may be arbitrarily increased or reduced for clarity of discussion.

FIG. 1 is a flow chart of one embodiment of a method for lithography process.

FIG. 2 is a flow chart of another embodiment of a method for lithography process.

FIGS. 3a through 3f are sectional views of one embodiment of a structure at various fabrication stages using the method of FIG. 1.

FIGS. 4a through 4f are sectional views of one embodiment of a structure at various fabrication stages using the method of FIG. 2.

FIG. 5 is a schematic view of one embodiment of a resolution enhancement material (REM).

FIG. 6 is a schematic view of another embodiment of a REM.

### DETAILED DESCRIPTION

It is to be understood that the following disclosure provides many different embodiments, or examples, for implementing different features of the disclosure. Specific examples of components and arrangements are described below to simplify the present disclosure. These are, of course, merely examples and are not intended to be limiting. In addition, the present disclosure may repeat reference numerals and/or letters in the various examples. This repetition is for the purpose of simplicity and clarity and does not in itself dictate a relationship between the various embodiments and/or configurations discussed. Moreover, the formation of a first feature over or on a second feature in the description that follows may include embodiments in which the first and second features are formed in direct contact, and may also include embodiments in which additional features may be formed interposing the first and second features, such that the first and second features may not be in direct contact.

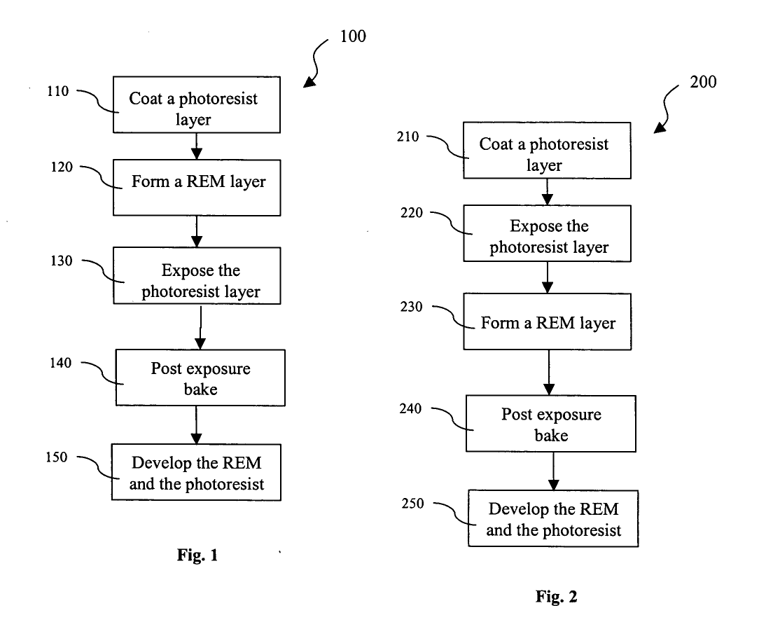

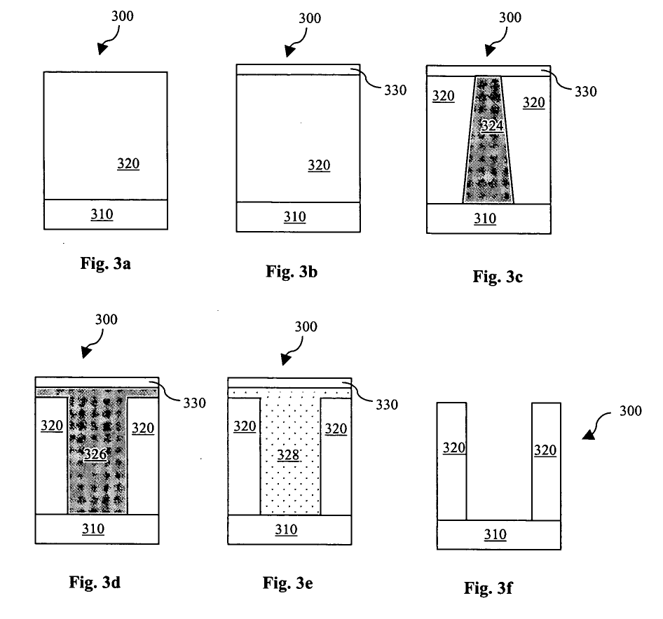

FIG. 1 is a flow chart of a method 100 for lithography processing. The method 100 is described below with additional reference to FIGS. 3a through 3f, sectional views of one embodiment of a structure 300 at various fabrication stages.

The method 100 begins at step 110 by forming a photoresist (resist) layer 320 on a substrate 310, as shown in FIG. 3a. The substrate 310 can be a semiconductor wafer or a photomask (mask). The semiconductor wafer may comprise an elementary semiconductor, a compound semiconductor, an alloy semiconductor, or combinations thereof. The semiconductor wafer may further comprise doped region therein. The semiconductor wafer may further comprise a plurality of patterned dielectric layers and patterned conductive layers combined to form interconnections. The mask may comprise a transparent substrate and an absorption layer. The transparent substrate may use fused silica (SiO2) relatively free of defects, calcium fluoride, or other suitable material. The absorption layer may be formed using a plurality of processes and materials, such as depositing a metal film made with chromium (Cr) and iron oxide, or an inorganic film made with MoSi, ZrSiO, SiN, and/or TiN. The absorption layer may be patterned to have one or more openings where light may travel through without being absorbed and have one or more absorption areas where light may be completely or partially blocked. The mask may comprise a pattern incorporating lithography technologies including phase shift mask (PSM) and optical proximate correction (OPC). The mask may be used for semiconductor wafer patterning. The method 100 and other methods described according to the present disclosure may be used to pattern a semiconductor wafer, a mask, a portion of the semiconductor wafer, or a portion of the mask.

The photoresist layer 320 may be disposed on the substrate 310 by a method such as spin-on coating. A soft baking and chilling process may be implemented after the photoresist layer is formed. The photoresist layer 320 may comprise chemical amplification photoresist (CA resist). The CA resist comprises photosensitive material referred to as photoacid generator (PAG). A photon induces decomposition of PAG and forms a small amount of acid, which further induces a cascade of chemical transformations in the resist layer, typically during a post-exposure bake (PEB) step. The photoresist layer 320 may have a thickness ranging between about 100 nm and 400 mn.

An adhesion layer may be formed on the substrate prior to the forming a photoresist layer. The adhesion layer may act to modify surfaces to enhance adhesion between the substrate and the photoresist layer. One example of the adhesion layer may comprise hexamethyldisilazane (HMDS). Alternatively, a bottom anti-reflection layer (BARC) may be formed on the substrate prior to the forming a photoresist layer. In another embodiment, a layer may be formed and function both as an adhesion layer and a BARC layer. A baking and chilling process may be followed after forming the adhesion layer and/or BARC layer.

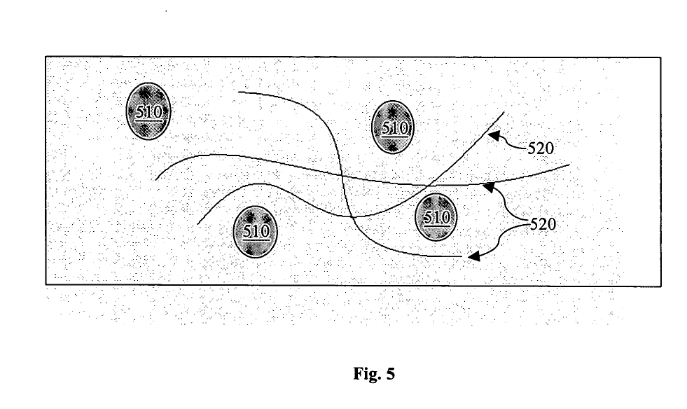

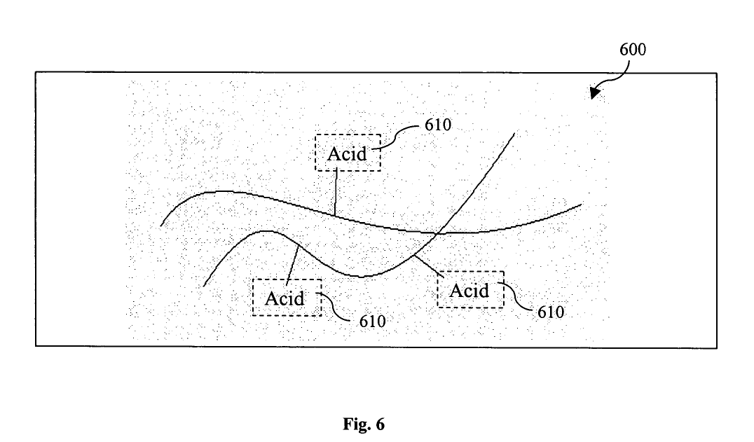

The method 100 may proceed to step 120 by forming a resolution enhancement material (REM) layer 330 on the photoresist layer 320 as illustrated in FIG. 3b. The REM layer 330 comprises an acid component. In one embodiment illustrated in FIG. 5, the REM layer 330 may comprise acid compound 510 doped in a developable polymer 520. For example, the acid compound 510 can be acetic acid and the developable polymer 520 can be hydroxyl ethyl methacrylate (HEMA) and MethylMethAcrylate (MMA) copolymer. In another embodiment illustrated in FIG. 6, the REM layer 330 may comprise a developable polymer 600 having acid functional groups 610. For example, the developable polymer 600 may comprise methacryl acid (MA), HEMA, and MMA copolymer, wherein the MA includes the acid functional groups 610. In another embodiment, the REM layer may comprise a developable polymer, acid compound doped therein, and acid functional groups linked thereto. The distribution of the acid functional groups and acid compound may be tuned to optimize photoresist patterning. The concentration of the acid component, comprising acid compound and/or acid functional groups, may range between about 1% and about 10% in weight percent, defined as weight of the acid component over weight of the REM. The REM may be first prepared and then applied on the photoresist layer. The REM may be further tuned in terms of material, composition, and thickness to have an anti-reflection function.

The REM layer 330 may be disposed on the photoresist layer 320 by a method such as spin-on coating. The REM layer 330 may be further baked and cooled after its forming. The REM layer 330 may have a thickness ranging from about 5 nm to about 100 nm.

The method 100 may proceed to step 130 wherein the resist layer on the substrate 310 is patterned, such as by exposure to a radiation beam. The radiation beam may be a photon beam. For example, the resist layer on a semiconductor wafer may be exposed to an ultraviolet (UV) light through a mask having a predefined pattern. The exposing process may be implemented using a stepper by a step-and-repeat method or using a scanner by a step-and-scan method. Other options to the radiation beam other than photon beams include electron beam and ion beam. For example, the resist layer on a mask may be exposed to an electron beam (e-beam) by an e-beam exposure system (e-beam writer). A pattern may be written to the resist layer according to a predefined pattern using the e-beam writer. The exposing process may be further extended to include other technologies such as a maskless exposing process.

Referring to FIG. 3c, as an example, a portion of the resist layer 324 is exposed and transformed by acid produced therein during the exposing process. For example, the radiation beam may decompose a photoacid generator (PAG) and cause an amount of acid to be formed within the portion of the resist layer 324. The profile of the portion 324 depends on depth-of-field (DOF) of the lithography system utilizing the exposing process. A limited DOF may result in a relatively small quantity of photo acids being produced in a defocused area. Such a limited DOF (such as a larger DOF) may result in an undercut photoresist profile (such as the portion 324 illustrated in FIG. 3c), as opposed to an ideal photoresist profile having vertical sidewalls.

As will be described below, the undercut profiles of the portion 324 may be minimized or avoided by increasing the quantity of acids in the defocused area, so that a profile of acid similar to the ideal resist profile may be produced. The increased quantity of acids in the defocused area can be accomplished by the REM layer 330. The acid component in the REM layer 330, including acid compound doped in and/or acid functional groups formed to a developable polymer, may diffuse or migrate into the resist layer 320 and forms an acid profile having a gradient distribution in the resist layer 320 in addition to the acid distribution generated by the exposing process. The acid contribution from both the exposing process and the diffused acid from the REM layer adds up to produce an overall acid profile 326, as shown in FIG. 3d, which is more close to an improved exposed resist profile having vertical sidewalls. The diffusion or migration of the acid component of the REM layer 330 may start as soon as it is applied to the resist and continues through and beyond the exposing process. The portion 324 in FIG. 3c only illustrates an acid profile in the resist layer contributed only from the exposing process.

Referring to FIG. 3e, the method 100 may proceed to step 140 to implement a thermal baking, referred to as a post exposure bake (PEB). The PEB may induce a cascade of chemical transformations in the portion of the resist layer 326 wherein the portion 326 is transformed to a portion 328 having an increased solubility of the resist in a developer. Usually, other soft bakes may have a temperature lower than the temperature of the PEB such as about 10 to 20° C. lower.

The method 100 may proceed to step 150 wherein the REM layer and the resist layer on the substrate are developed such that the REM layer 330 and the resist portion 328 are more soluble, dissolved, and washed away during the developing process. A resist layer is patterned as illustrated in FIG. 3f. The patterned resist layer 320 on the substrate 310 has an improved profile close to the ideal exposed resist profile having vertical sidewalls. The improved resist pattern is enhanced by the addition of the REM layer 330.

The method described above may only present a subset of processing steps associated with a lithography process. The method may further include other steps such as cleaning, soft baking, and chilling in a proper sequence. For example, the developed resist layer 320 may be further baked and chilled.

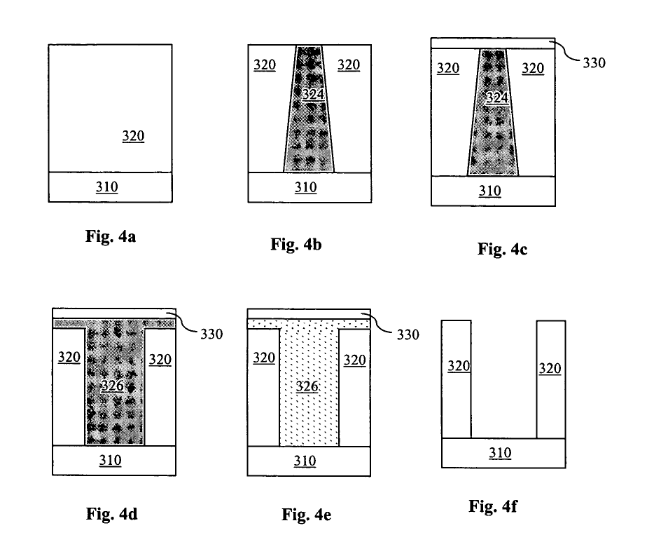

An alternative method 200 for lithography processing using the REM may include the REM coating and the exposing processes in a different sequence, as illustrated in the flow chart of FIG. 2. The method 200 is described below as opposed to the method 100, with additional reference to FIGS. 4a through 4f, sectional views of one embodiment of a structure 300 during various fabrication stages,

Referring to FIG. 4a, the method 200 may begin at step 210 by forming a resist layer 320 on a substrate 310 which is substantially similar to the 110 of the method 100 in terms of composition, formation, and structure.

Referring to FIG. 4b, the method 200 may proceed to step 220 wherein the resist layer 320 on the substrate 310 is exposed to a radiation beam to pattern the resist layer 320. The 220 may be substantially similar to the step 130 of the method 100.

Referring to FIG. 4c, the method 200 then proceeds to step 230 wherein a REM layer 330 is formed on the resist layer 320. The step 230 may be substantially similar to the step 120 of the method 100. However, the baking and chilling process after the formation of the REM layer may be skipped, or incorporated into next step 240.

At step 240, the resist layer is thermal baked in a PEB process. The PEB process at step 240 may be substantially similar to step 140 of the method 100. However, the thermal profile of the PEB process at step 240 may be defined so that the soft baking and chilling process after the formation of the REM layer at step 230 may be skipped.

Next at step 250, the REM layer and the resist layer on the substrate may be developed so that the REM layer 330 and the resist portion 328 are more soluble, as illustrated in FIG. 4e. The REM layer 330 and the resist portion 328 are dissolved and washed away during the developing process. A patterned resist layer 320 on the substrate 310, as illustrated in FIG. 4f, has an improved profile close to the ideal exposed resist profile having vertical sidewalls. The improved resist pattern is enhanced by the addition of the REM layer 330. The step 250 may be substantially similar to the step 150 of the method 100.

Thus, the present disclosure provides a method for lithography processing. The method comprises forming a resist layer on a substrate and forming a resolution enhancement material (REM) layer on the resist layer wherein the REM layer comprises an acid component.

In this method, the REM layer may further comprise a developable polymer. The developable polymer may comprise hydroxyl ethyl methacrylate (HEMA) and MethylMethAcrylate (MMA) copolymer. The acid component may comprise an acid compound doped in a developable polymer. The acid compound may comprise acetic acid. The acid component may comprise acid functional groups. The REM layer may comprise methacryl acid (MA), HEMA, and MMA copolymer. The acid component may have a concentration ranging from about 1% to about 10% in weight percent. The REM layer may have a thickness ranging between about 5 nm and 100 nm. The REM layer may be formed using a spin-on coating process. The photoresist layer may comprise a chemical amplification (CA) photoresist.

The method may further comprise exposing the photoresist layer using a radiation beam, baking the photoresist layer after the exposing, and developing the REM layer and the photoresist layer. The process of exposing the photoresist layer may be performed after the REM layer is formed. The REM layer may function as a top anti-reflective coating (TAR) layer. Alternatively, the process of exposing the photoresist layer may be performed prior to the forming a REM layer. The radiation beam may be selected from the group consisting of photon beam, electron beam, and ion beam. The method may further comprise forming a bottom anti-reflective coating (BARC) layer prior to the forming a photoresist layer. The method may further comprise forming an adhesion layer prior to the forming a photoresist layer. The substrate may be selected from the group consisting of a semiconductor wafer and a photomask substrate.

The present disclosure also provides a method comprising forming a photoresist layer on a substrate and forming a resolution enhancement material (REM) layer on the photoresist layer, wherein the REM layer comprises a component selected from the group consisting of acid compound and acid function group. After forming the REM layer, the photoresist layer is exposed using a radiation beam. The method may further comprise baking the photoresist layer after exposing and developing the REM layer and the photoresist layer after baking. The REM layer may further comprises a developable polymer.

The present disclosure further provides a method comprising forming a photoresist layer on a substrate, exposing the photoresist layer using a radiation beam, and forming a resolution enhancement material (REM) layer on the photoresist layer after exposing the photoresist layer. The REM layer may comprise a component selected from the group consisting of acid compound and acid function group. The method may further comprise baking the photoresist layer after the forming the REM layer and developing the REM layer and the photoresist layer after the baking. The REM layer may comprise a developable polymer.

According to the present disclosure, a REM layer is formed on a photoresist layer and incorporated into a lithography process. A defocused region caused by limited or improper DOF can be compensated, and the resolution, critical dimension, and profile of the patterned photoresist are enhanced. The REM may comprise acid functional groups and/or acid compound. The REM layer may be formed prior to or post an exposing process. The exposing process may be utilized using a photon beam, an electron beam, or an ion beam. The method can be used to fabricating a semiconductor wafer, a mask, and other proper substrates.

Although only a few exemplary embodiments of this disclosure have been described in details above, those skilled in the art will readily appreciate that many modifications are possible in the exemplary embodiments without materially departing from the novel teachings and advantages of this disclosure. Also, features illustrated and discussed above with respect to some embodiments can be combined with features illustrated and discussed above with respect to other embodiments. Accordingly, all such modifications are intended to be included within the scope of this disclosure.

What is claimed is:

1. A method for lithography, comprising:
forming a photoresist layer on a substrate; and
forming a resolution enhancement material (REM) layer on the photoresist layer wherein the REM layer comprises an acid component.

2. The method of claim 1 wherein the REM layer further comprises a developable polymer.

3. The method of claim 2 wherein the developable polymer comprises hydroxyl ethyl methacrylate (HEMA) and MethylMethAcrylate (MMA) copolymer.

4. The method of claim 1 wherein the acid component comprises an acid compound doped in a developable polymer.

5. The method of claim 4 wherein the acid compound comprises acetic acid.

6. The method of claim 1 wherein the acid component comprises acid functional groups.

7. The method of claim 1 wherein the REM layer comprises methacryl acid (MA), HEMA, and MMA copolymer.

8. The method of claim 1 wherein the acid component has a concentration ranging from about 1% to about 10% in weight percent.

9. The method of claim 1 wherein the REM layer has a thickness ranging between about 5 nm and 100 nm.

10. The method of claim 1 wherein the forming the REM layer is utilized using a spin-on coating method.

11. The method of claim 1 wherein the photoresist layer comprises a chemical amplification (CA) photoresist.

12. The method of claim 1 further comprising
exposing the photoresist layer using a radiation beam;
baking the photoresist layer after the exposing; and
developing the REM layer and the photoresist layer.

13. The method of claim 12 wherein the exposing the photoresist layer is performed after the forming a REM layer.

14. The method of claim 13 wherein the REM layer is a top anti-reflective coating (TAR) layer.

15. The method of claim 12 wherein the exposing the photoresist layer is performed prior to the forming a REM layer.

16. The method of claim 12 wherein the radiation beam is selected from the group consisting of photon beam, electron beam, and ion beam.

17. The method of claim 1 further comprising forming a bottom anti-reflective coating (BARC) layer prior to the forming a photoresist layer.

18. The method of claim 1 further comprising forming an adhesion layer prior to the forming a photoresist layer.

19. The method of claim 1 wherein the substrate is selected from the group consisting of a semiconductor wafer and a photomask substrate.

20. A method for lithography, comprising:
forming a photoresist layer on a substrate;
forming a resolution enhancement material (REM) layer on the photoresist layer, wherein the REM layer comprises a component selected from the group consisting of acid compound and acid function group; and
exposing the photoresist layer using a radiation beam after forming the REM layer.

21. The method of claim 20 further comprising:
baking the photoresist layer after the exposing; and
developing the REM layer and the photoresist layer after the baking.

22. The method of claim 20 wherein the REM layer further comprises a developable polymer.

23. A method for lithography, comprising:
forming a photoresist layer on a substrate;
exposing the photoresist layer using a radiation beam; and
forming a resolution enhancement material (REM) layer on the photoresist layer after the exposing the photoresist layer, wherein the REM layer includes an acid compound and an acid function group.

24. The method of claim 23 further comprising:
baking the photoresist layer after the forming the REM layer; and
developing the REM layer and the photoresist layer after the baking.

25. The method of claim 23 wherein the REM layer comprises a developable polymer.
